(19) United States
(12) Patent Application Publication
(10) Pub. No.: US 2026/0186054 A1
(43) Pub. Date: Jul. 2, 2026

(54) DATA DUMPING CIRCUIT, SENSING AND LOCKING CIRCUIT, AND DEBUG CIRCUIT

(71) Applicant: Realtek Semiconductor Corp., HsinChu (TW)

(72) Inventor: Yung-Cheng Chen, HsinChu (TW)

(73) Assignee: Realtek Semiconductor Corp., HsinChu (TW)

(21) Appl. No.: 19/424,079

(22) Filed: Dec. 17, 2025

(30) Foreign Application Priority Data
Dec. 30, 2024 (TW) 113151533

(51) Int. Cl. G01R 31/3185; G01R 31/317

(52) U.S. Cl. CPC G01R 31/318536; G01R 31/31705; G01R 31/31727

(57) ABSTRACT

A data dumping circuit is coupled to a combinational logic circuit, and includes a sensing and locking circuit and a scan chain circuit. The sensing and locking circuit is arranged to sense a characteristic value of the combinational logic circuit, and generate a scan enabling signal in response to the characteristic value being determined to be changed. The scan chain circuit is coupled to multiple flip-flops, and operates in a scan mode in response to the scan enabling signal, wherein in the scan mode, the scan chain circuit sequentially outputs a value stored in each of the multiple flip-flops for acting as dumping data.

### BACKGROUND OF THE INVENTION

### 1. FIELD OF THE INVENTION

The present invention is related to a debug circuit and a data dumping circuit for error detection, which can immediately lock and dump error data and effectively locate a source of a failure circuit when an error occurs in a combinational logic circuit.

### 2. DESCRIPTION OF THE PRIOR ART

A typical circuit system with specific functions usually includes one or more integrated circuits (ICs), and combinational logic circuits within each IC also contain a large number of electronic components. During operations of the circuit system, certain components or circuits may fail due to factors such as increased system load, voltage drop, power ripple, or temperature variations. When a component or a circuit fails, the continuously operating circuit system may generate errors, such as incorrect values or incorrect data, which may propagate and spread to downstream circuits until the errors are eventually detected.

Since it is difficult to predict when or where an error will be detected, by the time the error is identified, the error may have already deviated significantly from the source of the failure circuit in terms of either an operation time or a transmission distance, thereby greatly increasing the complexity of circuit debugging.

### SUMMARY OF THE INVENTION

It is therefore one of the objectives of the present invention to provide a circuit and an associated method that can effectively locate a source of a failure circuit within a combinational logic circuit, in order to address the above-mentioned issues.

According to an embodiment of the present invention, a data dumping circuit is provided. The data dumping circuit is coupled to a combinational logic circuit, and comprises a sensing and locking circuit and a scan chain circuit. The sensing and locking circuit is arranged to sense a characteristic value of the combinational logic circuit, and generate a scan enabling signal in response to the characteristic value being determined to be changed. The scan chain circuit is coupled to multiple flip-flops, and operates in a scan mode in response to the scan enabling signal, wherein in the scan mode, the scan chain circuit sequentially outputs a value stored in each of the multiple flip-flops for acting as dumping data.

According to an embodiment of the present invention, a sensing and locking circuit is provided. The sensing and locking circuit is coupled to a combinational logic circuit, and comprises a sensor device and a controller circuit. The sensor device is coupled to a node of the combinational logic circuit, and is arranged to continually sense a characteristic value of the combinational logic circuit through the node, and generate an activation signal in response to the characteristic value being detected to be lower than a first threshold value or greater than a second threshold value. The controller circuit is arranged to generate a scan enabling signal in response to the activation signal, and notify a processor circuit to receive dumping data from a scan chain circuit. Operations of the combinational logic circuit are suspended in response to the scan enabling signal, and the dumping data comprises multiple values stored in the combinational logic circuit.

According to an embodiment of the present invention, a debug circuit is provided. The debug circuit is coupled to a combinational logic circuit, and comprises a data dumping circuit and a processor circuit. The data dumping circuit is coupled to the combinational logic circuit, and is arranged to output multiple values stored in the combinational logic circuit in response to a variation of a characteristic value of the combinational logic circuit. The processor circuit is arranged to receive the dumping data, and determine which of multiple logic circuits comprised in the combinational logic circuit is a failure circuit according to the dumping data.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating multiple events labeled along a time axis.

FIG. 2 is a block diagram of a debug circuit according to an embodiment of the present invention.

FIG. 3 is a block diagram of a debug circuit and a data dumping circuit included in the debug circuit according to an embodiment of the present invention.

FIG. 4 is a signal timing diagram according to an embodiment of the present invention.

FIG. 5 is a diagram illustrating an example of determination of a failure circuit according to an embodiment of the present invention.

FIG. 6 is a flow chart of a debug method according to an embodiment of the present invention.

### DETAILED DESCRIPTION

In modern circuit design technologies, during an integrated circuit (IC) design phase, simulation software is utilized to test circuits for ensuring the circuits operate correctly, and fix any detected errors. As there will still be differences between the environment created by the simulation software and the real hardware environment (e.g., hardware environment including factors such as chips, packaging, printed circuit boards (PCBs), and power supply), there is inevitably a certain discrepancy between the circuit characteristics simulated by the software and those of the chips finally produced through the manufacturing process. In addition, the simulation software is typically only capable of simulating a small-scale circuit and cannot be applied to a circuit system integrating multiple ICs. Therefore, it is not possible to rely entirely on the software to simulate actual operating conditions of a circuit. When errors occur during actual circuit operations, it is also difficult to rely solely on the simulation software for debugging.

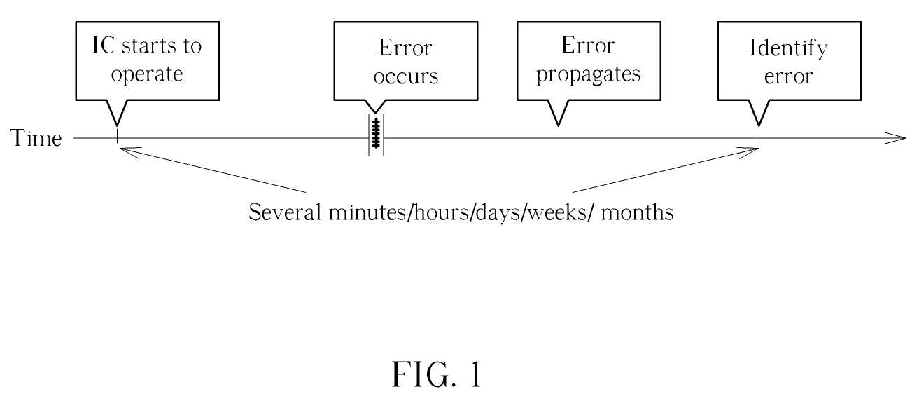

FIG. 1 is a diagram illustrating multiple events labeled along a time axis for illustrating the phenomenon of error propagation in a circuit system. After an IC (or a chip resulting from the packaging of the IC) starts to operate, certain components or circuits may fail at a certain time point due to factors such as increased system load, voltage drops caused by changes in current and resistance (e.g., IR drop), power supply ripple, or temperature fluctuations, which may further lead to errors such as incorrect values or incorrect data. Since the incorrect values or the incorrect data do not immediately halt the operations of the IC, the IC continues to operate based on the incorrect values or the incorrect data, causing the error to propagate through subsequent stage circuits. As a result, the scope of the error expands continuously until it is eventually detected. Because it is difficult to predict when or where the error will be identified, by the time the error is recognized, the IC may have been operating for several minutes, hours, days, or even weeks or months. Additionally, the error may have propagated far from a source of a failure circuit. Therefore, identifying the source of the failure circuit at the moment the error is detected becomes extremely challenging.

In order to address this issue, the present invention proposes a debug circuit that can effectively locate a source of a failure circuit within a combinational logic circuit, a data dumping circuit for error detection, and a corresponding debug method.

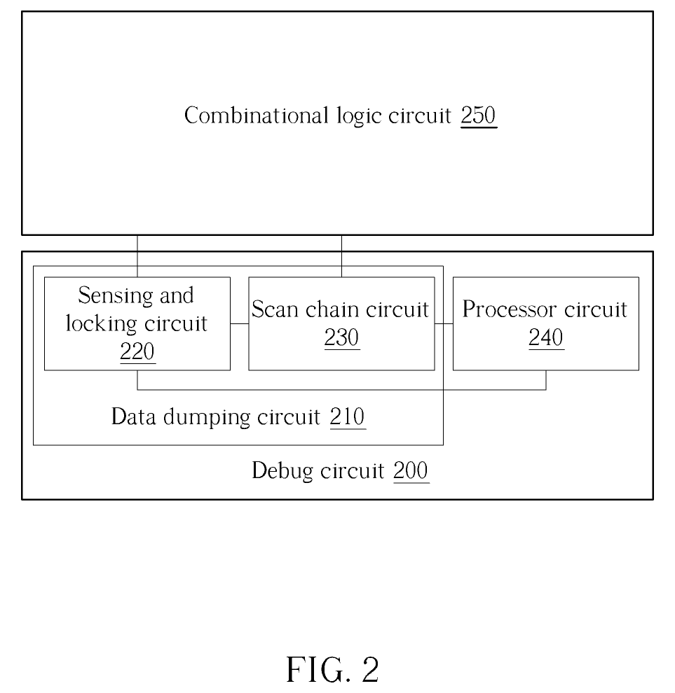

FIG. 2 is a block diagram of a debug circuit 200 according to an embodiment of the present invention. As shown in FIG. 2, the debug circuit 200 may be coupled to a combinational logic circuit 250, and may include a data dumping circuit 210 and a processor circuit 240. The combinational logic circuit 250 may be a circuit system with specific functions, such as an IC, a chip, a partial circuit within the IC or the chip, or a large-scale circuit integrating multiple ICs or multiple chips. The combinational logic circuit 250 may include multiple logic circuits, and more particularly, may be a combination of the multiple logic circuits. The data dumping circuit 210 may be coupled to the combinational logic circuit 250.

According to an embodiment of the present invention, the data dumping circuit 210 may immediately output multiple values stored in the combinational logic circuit 250 (e.g., values stored in multiple flip-flops or multiple other storage circuits) in response to a variation of a characteristic value when the combinational logic circuit 250 operates, wherein the multiple values act as dumping data. According to an embodiment of the present invention, the data dumping circuit 210 may continually detect one or more characteristic values of the combinational logic circuit 250. When it is detected that the characteristic value changes, the data dumping circuit 210 may control operations of the combinational logic circuit 250 to be suspended, thereby locking the multiple values stored in the combinational logic circuit 250 (i.e., the values are held and will not change).

According to an embodiment of the present invention, the data dumping circuit 210 may include a sensing and locking circuit 220 and a scan chain circuit 230. The sensing and locking circuit 220 may continually sense a characteristic value of the combinational logic circuit 250, and generate a scan enabling signal in response to the characteristic value being determined to be changed. The scan chain circuit 230 may be coupled to the flip-flops storing multiple values that can assist in identifying a source of an error, and may control the flip-flops to sequentially output a corresponding value as the dumping data in response to the scan enabling signal.

According to an embodiment of the present invention, the processor circuit 240 may receive the dumping data, and determine which of the multiple logic circuits included in the combinational logic circuit 250 is a failure circuit according to the dumping data. As mentioned above, when the characteristic value is detected to be changed, the sensing and locking circuit 220 may control the operations of the combinational logic circuit 250 to be suspended for locking the multiple values stored in the combinational logic circuit 250, and enable the scan chain circuit 230 via the scan enabling signal for controlling the flip-flops to sequentially output a corresponding value as the dumping data. As a result, the dumping data can reflect an internal operating state of the combinational logic circuit 250 at the time the characteristic value changes.

According to an embodiment of the present invention, the sensing and locking circuit 220 may include one or more sensor devices, and each sensor device is coupled to a node of the combinational logic circuit 250. For example, during a circuit design phase, a corresponding sensor device may be configured on a specific node of the combinational logic circuit 250 in advance, in order to sense a characteristic value of the specific node. According to an embodiment of the present invention, the specific node may be a node within the combinational logic circuit 250 that is more sensitive to current fluctuations and/or voltage fluctuations, a node coupled to components that are relatively fragile and prone to failure, or a node connected to a larger load or located farther from the power supply (i.e., a node with a longer power delivery path). Since these components or nodes are more likely to experience unexpected state changes, operational errors, or failures due to factors such as voltage drops, power supply ripple, or temperature variations, changes in the characteristic values of these nodes can indicate errors or failures of the components (hereinafter collectively referred to as “failures” for brevity).

According to an embodiment of the present invention, the characteristic value continually sensed by the sensor device may be a value that can be measured in the combinational logic circuit 250, such as a voltage value, a current value, or a temperature value, but the present invention is not limited thereto. In embodiments of the present invention, the sensor device may include a voltage sensor or a temperature sensor.

In addition, according to an embodiment of the present invention, the sensing and locking circuit 220 may include a controller circuit coupled to the sensor device. The controller circuit may control output of the dumping data when the sensor device detects the variation of the characteristic value.

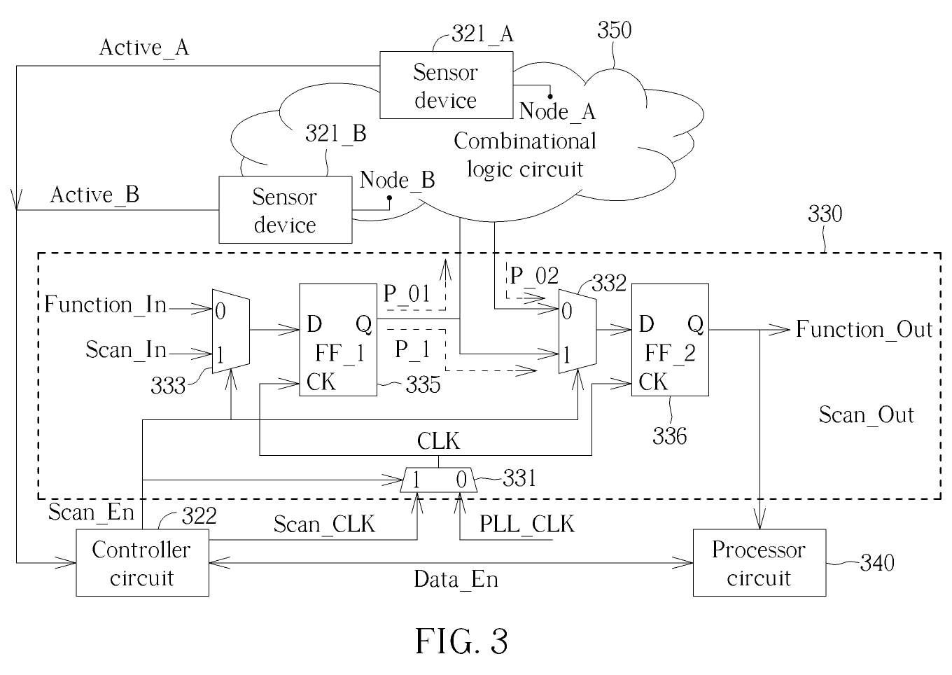

FIG. 3 is a block diagram of a debug circuit and a data dumping circuit included in the debug circuit according to an embodiment of the present invention. In this embodiment, the data dumping circuit may include a sensing and locking circuit and a scan chain circuit 330, wherein the sensing and locking circuit may include sensor devices 321_A and 321_B and a controller circuit 322.

According to an embodiment of the present invention, the debug circuit may be coupled to a combinational logic circuit 350, and may include the data dumping circuit and a processor circuit 340. The combinational logic circuit 350 is similar to the combinational logic circuit 250, and more particularly, is a circuit system with specific functions, and includes multiple logic circuits.

According to an embodiment of the present invention, the sensor device 321_A may be coupled to a node Node_A of the combinational logic circuit 350, and may continually sense a first characteristic value of the combinational logic circuit 350 via the node Node_A. When detecting that the first characteristic value is lower than a corresponding low threshold value or greater than a corresponding high threshold value, the sensor device 321_A may determine the first characteristic value changes and generate an activation signal Active_A. Similarly, the sensor device 321_B may be coupled to a node Node_B of the combinational logic circuit 350, and may continually sense a second characteristic value of the combinational logic circuit 350 via the node Node_B. When detecting that the second characteristic value is lower than a corresponding low threshold value or greater than a corresponding high threshold value, the sensor device 321_B may determine the second characteristic value changes and generate an activation signal Active_B.

According to an embodiment of the present invention, the controller circuit 322 may generate a scan enabling signal Scan_En and a scan clock signal Scan_CLK in response to the activation signal Active_A or the activation signal Active_B, and notify the processor circuit 340 to receive the dumping data.

According to an embodiment of the present invention, the controller circuit 322 may receive a control signal Data_En from the processor circuit 340 in order to determine whether the processor circuit 340 is ready to receive the dumping data. For example, when being ready to receive the dumping data, the processor circuit 340 may notify the controller circuit 322 via the control signal Data_En.

According to an embodiment of the present invention, the controller circuit 322 may include an activation signal receiving circuit for receiving the activation signals, a control signal receiving circuit for receiving the control signal Data_En, an enabling signal generating circuit for generating the scan enabling signal Scan_En, and a clock signal generating circuit for generating the scan clock signal Scan_CLK.

According to an embodiment of the present invention, the processor circuit 340 may be a computer or a test machine, or may be a processor circuit included in the computer or the test machine.

According to an embodiment of the present invention, the scan chain circuit 330 may be coupled to or include multiple cascaded flip-flops and multiple multiplexers, such as multiple flip-flops 335 and 336, and multiple multiplexers 331, 332, and 333. According to an embodiment of the present invention, the above-mentioned flip-flops may actually be internal flip-flops of the combinational logic circuit 350. For example, the scan chain circuit 330 may be coupled to one or more flip-flops included in the combinational logic circuit 350 via one or more signal transmission lines, and the multiplexers and the flip-flops are connected in series to form a shift register. According to another embodiment of the present invention, the flip-flops may be dedicated flip-flops of the scan chain circuit 330. The flip-flops may be coupled to multiple internal nodes of the combinational logic circuit 350 in order to store a value of each node.

According to an embodiment of the present invention, the combinational logic circuit 350 and the flip-flops 335 and 336 included in or coupled to the scan chain circuit 330 may operate according to a system clock signal PLL_CLK, wherein the system clock signal PLL_CLK may be a clock signal generated by a phase locked loop (PLL) circuit.

According to an embodiment of the present invention, the multiplexer 331 may include a first input terminal receiving the system clock signal PLL_CLK, a second input terminal receiving the scan clock signal Scan_CLK, and an output terminal. The output terminal of the multiplexer 331 may be coupled to clock input terminals CK of the flip-flops 335 and 336, for providing an output clock signal CLK to the flip-flops 335 and 336. According to an embodiment of the present invention, the multiplexer 331 may select one of the system clock signal PLL_CLK and the scan clock signal Scan_CLK as the output clock signal CLK according to the scan enabling signal Scan_En.

According to an embodiment of the present invention, the multiplexer 332 may be coupled between the flip-flops 335 and 336. The multiplexer 332 may include a first input terminal receiving a signal from the combinational logic circuit 350 via a path P_02, a second input terminal coupled to a data output terminal Q of the flip-flop 335, and an output terminal. The output terminal of the multiplexer 332 may be coupled to a data input terminal D of the flip-flop 336 in order to select one of the signals from the combinational logic circuit 350 and an output terminal of the flip-flop 335 according to the scan enabling signal Scan En, for acting as an input signal of the flip-flop 336.

According to an embodiment of the present invention, the multiplexer 333 may include a first input terminal receiving a function input signal Function_In, a second input terminal receiving a scan input signal Scan_In, and an output terminal. According to an embodiment of the present invention, the output terminal of the multiplexer 333 may be coupled to a data input terminal of the flip-flop 335 in order to select one of the function input signal Function_In and the scan input signal Scan_In according to the scan enabling signal Scan_En, for acting as an input signal of the flip-flop 335.

According to an embodiment of the present invention, the scan chain circuit 330 may switch between a function mode and a scan mode according to the scan enabling signal Scan_En. For example, the controller circuit 322 may set a value of the scan enabling signal Scan_En as a logic value “0” or a logic value “1”, and the scan chain circuit 330 may operate in the function mode or the scan mode according to the value of the scan enabling signal Scan_En.

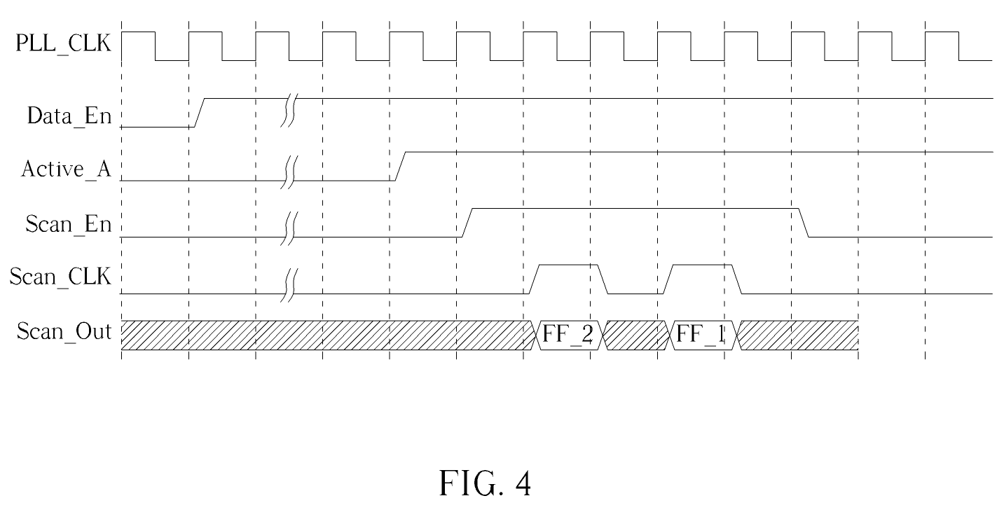

FIG. 4 is a signal timing diagram according to an embodiment of the present invention. Refer to FIG. 4 in conjunction with FIG. 3. The following will further describe operations of the debug circuit in different modes.

According to an embodiment of the present invention, a voltage level of the scan enabling signal Scan_En may be preset as a low level (e.g., the logic value “0”). At this moment, the processor circuit 340 or an external circuit may provide the function input signal Function_In, such that the combinational logic circuit 350 starts to operate according to the function input signal Function_In. In addition, the scan input signal Scan_In required for the scan mode may also be provided by the processor circuit 340 or the external circuit.

The scan chain circuit 330 may operate in the function mode in response to the low level state of the scan enabling signal Scan_En. In the function mode, the multiplexer 333 selects the function input signal Function_In as the input signal of the flip-flop 335, and the multiplexer 331 selects the system clock signal PLL_CLK as the output clock signal CLK, such that the flip-flop 335 provides the function input signal Function_In to the combinational logic circuit 350 via a path P_01 according to the system clock signal PLL_CLK.

Internal subsequent stage circuits of the combinational logic circuit 350 may perform operations based on the function input signal Function_In, and an operation result (which may not be a final result of operations performed by the combinational logic circuit 350, but may simply be an intermediate value that needs to be recorded during the operation process) can be provided to the multiplexer 332 via the path P_02. In the function mode, the multiplexer 332 may select an input signal carrying the operation result for outputting to the flip-flop 336. The flip-flop 336 may further provide the operation result to other internal subsequent stage circuits of the combinational logic circuit 350 via another path according to the system clock signal PLL_CLK (not shown in FIG. 3), or may output the operation result of the combinational logic circuit 350 as a function output signal Function_Out (shown in FIG. 3).

According to an embodiment of the present invention, the low level state of the scan enabling signal Scan_En may represent that both the sensor devices 321_A and 321_B have not yet detected any changes in the characteristic value. In addition, a voltage level of the control signal Data_En may be preset as a low level (e.g., the logic value “0”). When the processor circuit 340 is ready to receive the dumping data, the processor circuit 340 may pull up the voltage level of the control signal Data_En (or may set the voltage level of the control signal Data_En as a specific value) in order to notify the controller circuit 322 that it is ready to receive the dumping data.

According to an embodiment of the present invention, when either the sensor device 321_A or the sensor device 321_B detects the changes in the characteristic value (e.g., the characteristic value is lower than a corresponding low threshold value or greater than a corresponding high threshold value), the sensor device 321_A/321_B may generate a corresponding activation signal. In FIG. 4, a voltage level of the activation signal Active_A is changed to a high level (e.g., the logic value “1”) in order to represent that the activation signal Active_A is generated or an activation state is asserted.

In response to the high voltage level of the activation signal Active_A, the controller circuit 322 may correspondingly pull up the voltage level of the scan enabling signal Scan_En (e.g., set as a high voltage level, such as the logic value “1”). In an embodiment of the present invention, the low voltage level of the scan enabling signal Scan_En may represent that the scan enabling signal Scan_En has not been generated or the activation state has not been asserted. The controller circuit 322 may pull up the voltage level of the scan enabling signal Scan_En in order to generate the scan enabling signal Scan_En or assert the activation state.

In an embodiment of the present invention, the controller circuit 322 may control the scan chain circuit 330 to switch to the scan mode by generating the scan enabling signal Scan_En. In the scan mode, the multiplexer 331 selects the scan clock signal Scan_CLK as the output clock signal CLK. Since the combinational logic circuit 350 operates according to the system clock signal PLL_CLK, the controller circuit 322 may suspend the operations of the combinational logic circuit 350 by stopping outputting the system clock signal PLL_CLK, such that multiple values stored in the combinational logic circuit 350 can be locked (i.e., the values will be held in the flip-flops and will no longer change).

According to an embodiment of the present invention, in the scan mode, the scan chain circuit 330 utilizes switching of the multiplexer 332 coupled between the flip-flops 335 and 336 to control the flip-flops 335 and 336 to sequentially output stored values according to the scan clock signal Scan_CLK. That is, in the scan mode, the scan chain circuit 330 may control the flip-flops 335 and 336 to sequentially output multiple values stored in the combinational logic circuit 350 as the dumping data according to the scan clock signal Scan_CLK.

Specifically, in the scan mode, the signal output by the flip-flop 336 is a scan output signal Scan_Out. In response to the 1^{st} clock period of the scan clock signal Scan_CLK, the values stored in the flip-flop 336 may be output as the dumping data according to the scan output signal Scan_Out (labeled “FF_2” for representing the stored values of the flip-flop 336 in FIGS. 3 and 4). At this moment, the multiplexer 332 selects the output signal of the flip-flop 335 as the input signal of the flip-flop 336 in response to the high voltage level of the scan enabling signal Scan_En, such that the stored values of the flip-flop 335 are provided to the flip-flop 336 via a path P_1. Similarly, the scan input signal Scan_In is provided to the flip-flop 335 via the multiplexer 333.

In response to the 2^{nd} clock period of the scan clock signal Scan_CLK, the stored values of the flip-flop 336 (which are the values previously stored in the flip-flop 335) are output as the dumping data according to the scan output signal Scan_Out (labeled “FF_1” in FIGS. 3 and 4 for representing the stored values of the flip-flop 335). In this way, the dumping data output in the scan mode may include values temporarily stored in the flip-flops 335 and 336 when the characteristic value of the combinational logic circuit 350 changes.

According to an embodiment of the present invention, after receiving the dumping data, the processor circuit 340 may be arranged to determine which of multiple logic circuits included in the combinational logic circuit 350 is a failure circuit according to the dumping data. In addition, the processor circuit 340 may be further arranged to determine which of the multiple logic circuits included in the combinational logic circuit 350 is a failure circuit according to a dependency of multiple signals generated by the multiple logic circuits.

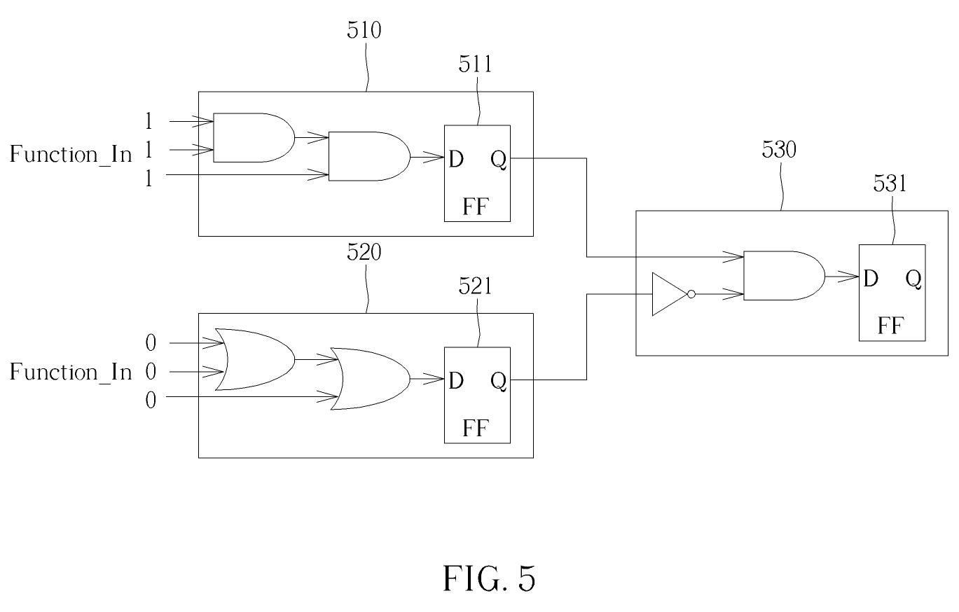

FIG. 5 is a diagram illustrating an example of determination of a failure circuit according to an embodiment of the present invention. In this embodiment, a combinational logic circuit includes sub-circuits 510, 520, and 530, wherein each sub-circuit may be a small-scale combinational logic circuit including multiple logic circuits. In addition, the sub-circuits 510, 520, and 530 may include flip-flops 511, 521, and 531, respectively. The text “FF” shown in FIG. 5 represents values stored by the flip-flops. In order to simplify the diagram, the clock input terminal of each flip-flop is omitted in FIG. 5.

Assume that for the function input signal Function_In, three input signals corresponding to the sub-circuit 510 are logic values “1”, and three input signals corresponding to the sub-circuit 520 are logic values “0”. By simulating circuit operations, the processor circuit 240/340 may determine correct outputs of the flip-flops 511, 521, and 531 in the function mode are logic values “1”, “0”, and “1”, respectively.

If the processor circuit 240/340 determines current outputs of the flip-flops 511, 521, and 531 are logic values “1”, “1”, and “0” according to the dumping data obtained in the scan mode, the processor circuit 240/340 may determine the sub-circuits 520 and 530 output error values, and may preliminarily determine the failure circuits currently include the sub-circuits 520 and 530.

The processor circuit 240/340 may further determine whether there is a dependency relationship between the sub-circuits. For example, when the signals generated by two sub-circuits exhibit a dependency, it is determined that there is a dependency relationship between the two sub-circuits. According to an embodiment of the present invention, each of the combinational logic circuits 250 and 350 can be assigned a corresponding code, and the dependency relationship between the sub-circuits or the signals can be established and stored as debug data associated with the corresponding code in advance. The processor circuit 240/340 may obtain corresponding debug data according to the code of the combinational logic circuit, identify a dependency relationship between the sub-circuits or the signals, and determine which of the circuits is an error source according to the dependency relationship. In this embodiment, since the sub-circuit 530 receives an output signal of the sub-circuit 520 as an input signal, a dependency is exhibited between the sub-circuits 520 and 530. Under a situation where both the sub-circuits 520 and 530 output error values, the processor circuit 240/340 can determine that the sub-circuit 520 is a source of a failure circuit.

According to an embodiment of the present invention, the processor circuit 240/340 may repeatedly adjust a threshold value used for detecting characteristic value changes, in order to control the sensitivity or timing of triggering output of the dumping data to the optimal state. For example, by identifying the optimal threshold value, the output of the dumping data can be triggered in time before errors caused by circuit failures begin to propagate, and falsely triggering the output of the dumping data before any circuit failure has actually occurred can be avoided. According to an embodiment of the present invention, the processor circuit 240/340 can select the optimal threshold value according to accuracy of the debug results obtained based on different threshold values (e.g., whether the output of the dumping data is triggered accurately and in time).

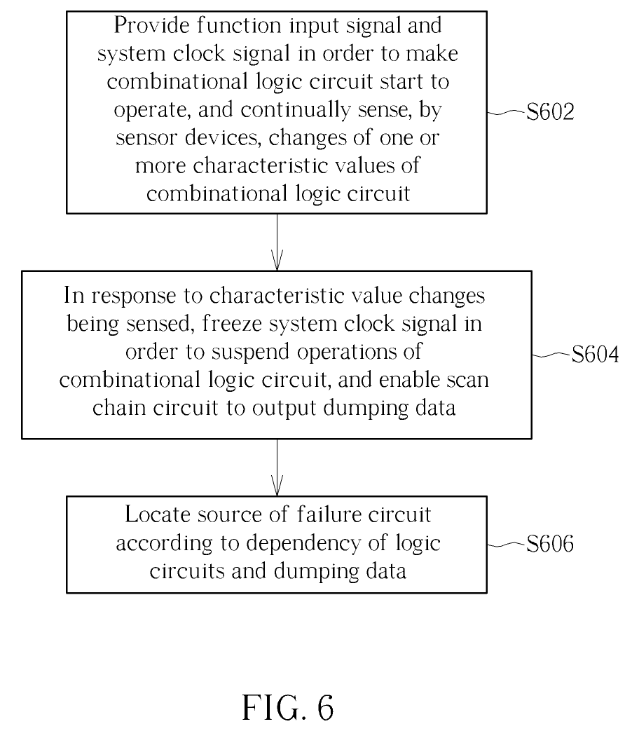

FIG. 6 is a flow chart of a debug method according to an embodiment of the present invention, wherein the debug method may include pre-configuring corresponding sensor devices at specific nodes of a combinational logic circuit, as well as the following steps executed by multiple components within a debug circuit.

In Step S602, a function input signal and a system clock signal are provided in order to make the combinational logic circuit start to operate, and changes of one or more characteristic values of the combinational logic circuit are continually sensed by the sensor devices. In response to the characteristic value changes being sensed, step S604 is entered; if not, the flow remains at Step S602.

In Step S604, in response to the characteristic value changes being sensed, the system clock signal is frozen (e.g., stops being output) in order to suspend operations of the combinational logic circuit, and a scan chain circuit is enabled to output dumping data.

In Step S606, a source of a failure circuit is located according to a dependency of logic circuits and the dumping data.

In summary, when a variation of a characteristic value is sensed, the debug method and the debug circuit proposed by the present invention can suspend operations of a combinational logic circuit in order to lock multiple values stored in the combinational logic circuit and support determination of an error source, and the multiple values can be sequentially output as dumping data. In this way, before errors start to propagate, the debug circuit of the present invention can immediately obtain the dumping data which reflects an internal operating state of the combinational logic circuit when the characteristic value changes, such that a source of a failure circuit can be determined accurately and effectively.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A data dumping circuit, coupled to a combinational logic circuit, comprising:
a sensing and locking circuit, arranged to sense a characteristic value of the combinational logic circuit, and generate a scan enabling signal in response to the characteristic value being determined to be changed; and
a scan chain circuit, coupled to multiple flip-flops, and operating in a scan mode in response to the scan enabling signal, wherein in the scan mode, the scan chain circuit sequentially outputs a value stored in each of the multiple flip-flops for acting as dumping data.

2. The data dumping circuit of claim 1, wherein the sensing and locking circuit comprises:
a sensor device, coupled to a node of the combinational logic circuit, and arranged to continually sense the characteristic value of the combinational logic circuit through the node, and determine changes in the characteristic value and generate an activation signal in response to the characteristic value being detected to be lower than a first threshold value or greater than a second threshold value; and
a controller circuit, arranged to generate the scan enabling signal and a scan clock signal in response to the activation signal, and notify a processor circuit to receive the dumping data.

3. The data dumping circuit of claim 2, wherein the scan chain circuit comprises:
a first multiplexer, comprising an output terminal coupled to a clock input terminal of the multiple flip-flops, and arranged to select one of a system clock signal and the scan clock signal as an output clock signal according to the scan enabling signal, wherein the combinational logic circuit operates according to the system clock signal; and when the scan chain circuit operates in the scan mode, the first multiplexer outputs the scan clock signal as the output clock signal.

4. The data dumping circuit of claim 2, wherein the multiple flip-flops are comprised in the combinational logic circuit; and in the scan mode, the scan chain circuit controls the multiple flip-flops to sequentially output the value according to the scan clock signal.

5. The data dumping circuit of claim 1, wherein the multiple flip-flops comprise a first flip-flop and a second flip-flop, and the scan chain circuit comprises:
a second multiplexer, coupled between the first flip-flop and the second flip-flop, wherein when the scan chain circuit operates in the scan mode, the second multiplexer selects an output signal of the first flip-flop as an input signal of the second flip-flop.

6. A sensing and locking circuit, coupled to a combinational logic circuit, comprising:
a sensor device, coupled to a node of the combinational logic circuit, and arranged to continually sense a characteristic value of the combinational logic circuit through the node, and generate an activation signal in response to the characteristic value being detected to be lower than a first threshold value or greater than a second threshold value; and
a controller circuit, arranged to generate a scan enabling signal in response to the activation signal, and notify a processor circuit to receive dumping data from a scan chain circuit;
wherein operations of the combinational logic circuit are suspended in response to the scan enabling signal, and the dumping data comprises multiple values stored in the combinational logic circuit.

7. The sensing and locking circuit of claim 6, wherein the sensor device comprises a voltage sensor and a temperature sensor.

8. A debug circuit, coupled to a combinational logic circuit, comprising:
a data dumping circuit, coupled to the combinational logic circuit, and arranged to output multiple values stored in the combinational logic circuit in response to a variation of a characteristic value of the combinational logic circuit, the multiple values acting as dumping data; and
a processor circuit, arranged to receive the dumping data, and determine which of multiple logic circuits comprised in the combinational logic circuit is a failure circuit according to the dumping data.

9. The debug circuit of claim 8, wherein the processor circuit is further arranged to determine which of the multiple logic circuits is the failure circuit according to a dependency of multiple signals generated by the multiple logic circuits.

10. The debug circuit of claim 8, wherein the data dumping circuit comprises:
a sensing and locking circuit, arranged to sense the characteristic value of the combinational logic circuit, and generate a scan enabling signal in response to the characteristic value being determined to be changed; and
a scan chain circuit, coupled to multiple flip-flops, wherein the multiple flip-flops store the multiple values, and the scan chain circuit controls the multiple flip-flops to sequentially output the multiple values in response to the scan enabling signal.

11. The debug circuit of claim 10, wherein the sensing and locking circuit comprises:
a sensor device, coupled to a node of the combinational logic circuit, and arranged to continually sense the characteristic value of the combinational logic circuit through the node, determine changes in the characteristic value, and generate an activation signal in response to the characteristic value being detected to be lower than a first threshold value or greater than a second threshold value; and
a controller circuit, arranged to generate the scan enabling signal and a scan clock signal in response to the activation signal, and notify the processor circuit to receive the dumping data.

12. The debug circuit of claim 11, wherein the scan chain circuit is switched between a function mode and a scan mode according to the scan enabling signal; and when the scan chain circuit operates in the scan mode, the scan chain circuit controls the multiple flip-flops to sequentially output the multiple values according to the scan clock signal.

13. The debug circuit of claim 12, wherein the scan chain circuit comprises:
a first multiplexer, comprising an output terminal coupled to a clock input terminal of the multiple flip-flops, and arranged to select one of a system clock signal and the scan clock signal as an output clock signal;
wherein the combinational logic circuit operates according to the system clock signal; when the scan chain circuit operates in the function mode, the first multiplexer outputs the system clock signal as the output clock signal; and when the scan chain circuit operates in the scan mode, the first multiplexer outputs the scan clock signal as the output clock signal.

14. The debug circuit of claim 13, wherein the controller circuit controls the first multiplexer not to output the system clock signal by generating the scan enabling signal, in order to suspend operations of the combinational logic circuit.

15. The debug circuit of claim 12, wherein the multiple flip-flops comprise a first flip-flop and a second flip-flop, and the scan chain circuit comprises:
a second multiplexer, coupled between the first flip-flop and the second flip-flop, wherein when the scan chain circuit operates in the scan mode, the second multiplexer selects an output signal of the first flip-flop as an input signal of the second flip-flop.
